(19) United States
(12) Patent Application Publication
(10) Pub. No.: US 2025/0069978 A1
(43) Pub. Date: Feb. 27, 2025

(54) THERMAL SPREADER

(71) Applicant: SK Hynix NAND Product Solutions Corp. (dba Solidigm), Rancho Cordova, CA (US)

(72) Inventors: Hardeep Singh, Vancouver (CA); Wayne Gregory, Sacramento, CA (US)

(21) Appl. No.: 18/237,059

(22) Filed: Aug. 23, 2023

(51) Int. Cl. H01L 23/367; H01L 21/52

(52) U.S. Cl. CPC H01L 23/3675; H01L 21/52

(57) ABSTRACT

A package and related method for manufacturing thereof, the package including multiple layers. The layers include an external layer with an external layer outer surface and an external layer inner surface, and an interface layer with an interface layer outer surface and an interface layer inner surface, where the interface layer outer surface is in contact with the external layer inner surface. The layers also include a thermal spreader layer with a thermal spreader outer surface and a thermal spreader inner surface, where the thermal spreader outer surface is in contact with the interface layer inner surface. The layers include circuitry, which is arranged proximate to and facing the thermal spreader inner surface. In some embodiments, the thermal spreader layer includes at least one thermally conductive channel to transfer heat along the at least one channel, the heat to be thermally transferred to the external layer via the interface layer.

### TECHNICAL FIELD

The present disclosure is directed to a thermal spreader and more particularly to a thermal spreader internal to a device enclosure.

### SUMMARY

In accordance with the present disclosure, packages and methods for manufacturing thereof are provided to improve the thermal distribution on an outer surface of the external layer of the package. The package may include multiple layers, including an external layer, an interface layer, a thermal spreader layer and circuitry, each layer arranged to improve thermal distribution of heat generated from the circuitry to the external layer. The package and methods for manufacturing thereof disclosed herein promote thermal transfer from a heat-generating electrical component of the circuitry to the external layer in a distributed manner to reduce any non-uniform temperature distribution (hereafter referred to as hot-spots) on the external layer outer surface. The circuitry of the package is arranged facing a thermal spreader layer inner surface and the circuitry also includes at least one heat-generating electrical component, with which a portion of the thermal spreader layer is in thermal contact. The thermal spreader layer is thermally-conductive and is arranged throughout the package in order for heat generated from the heat-generating electrical component to be transferred along the thermal spreader layer away from an area of the package at which the at least one heat-generating electrical component is positioned. The interface layer of the package is arranged with conductive portions along the edges of the package to ensure thermal transfer from the thermal spreader layer to the external layer. In addition, the interface layer includes insulation portions between (a) the portion of the thermal spreader layer that is in thermal contact with the heat-generating electrical component and (b) the external layer, to reduce the likelihood of hot-spots forming. The packages and methods disclosed herein are provided to improve thermal distribution of heat generated by at least one heat-generating electrical component of the circuitry. The improved thermal distribution ensures that the surface temperature of the external layer remains below the safety and regulatory requirement touch temperature limit and reduces or eliminates any chance of thermal throttling of the circuitry in the package.

In some embodiments, the package (e.g., a solid-state storage device package) is provided with circuitry (e.g., solid-state storage device) which faces the thermal spreader layer internal surface. The interface layer includes an interface layer inner surface which is in contact with a thermal spreader layer outer surface, and an interface layer outer surface which is in contact with an external layer inner surface. In some embodiments, the package includes an enclosure, wherein the enclosure includes the external layer and the external layer outer surface is the outer surface of the package or enclosure.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in one embodiment” or “in an alternate embodiment” appearing herein describe various embodiments and implementations, and do not necessarily all refer to the same embodiment. However, they are also not necessarily mutually exclusive.

FIG. 1 shows an illustrative exploded view diagram of a package with a thermal spreader layer, in accordance with some embodiments of the present disclosure;

FIG. 2 shows an illustrative cross-sectional diagram of a package with a thermal spreader layer, in accordance with some embodiments of the present disclosure;

FIG. 3 shows an illustrative plan view diagram of the package, similar to that of FIG. 2, in accordance with some embodiments of the present disclosure;

FIG. 4 shows an illustrative exploded view diagram of another implementation of a package with a thermal spreader layer, in accordance with some embodiments of the present disclosure;

FIG. 5 shows an illustrative diagram for temperature distributions along the external layer of a package without a thermal spreader layer, in accordance with some embodiments of the present disclosure;

FIG. 6 shows an illustrative diagram for temperature distributions along the external layer of a package with a thermal spreader layer, in accordance with some embodiments of the present disclosure;

FIG. 7 shows a flowchart of illustrative steps for manufacturing a package with a thermal spreader layer, in accordance with some embodiments of the present disclosure;

FIG. 8 shows a flowchart of illustrative steps for arranging the thermal spreader layer of a package, in accordance with some embodiments of the present disclosure; and

FIG. 9 shows a flowchart of illustrative steps of a subprocess for arranging an interface layer, as shown in FIG. 7, in accordance with some embodiments of the present disclosure.

### DETAILED DESCRIPTION

In accordance with the present disclosure, packages and methods for manufacturing thereof are provided for improved thermal distribution on the external layer outer surface. The package disclosed herein includes an external layer which includes an external layer outer surface and an external layer inner surface. In some embodiments, the external layer may be a part of a housing of an enclosure which encapsulates the layers disclosed herein. The package disclosed herein may be any suitable packaging of electrical components into any suitable form factor. For example, the package may be an enclosure containing one or more integrated circuits or dies. In some embodiments, the package itself can be an integrated circuit or enclosed die. In some embodiments, the external layer is thermally-conductive to act as a heat sink, dissipating heat generated from the circuitry. Any heat generated by the circuitry may refer to thermal output of heat-generating electrical components of the circuitry (e.g., high-performance integrated circuit chips or cores).

The package includes an interface layer with an interface layer outer surface in contact with the external layer inner surface. In some embodiments, the interface layer includes at least one insulation portion and at least one conductive portion. Each insulation portion is placed in contact with a part of the thermal spreader layer which is in thermal contact with a heat-generating electrical components of the circuitry. The insulation portions may be any thermally-insulative material. The insulation portions are arranged in order to reduce the thermal transfer from a heat-generating electrical component to the external layer by insulating the portion of the thermal spreader layer in thermal contact with the heat-generating electrical component from being in thermal contact with a portion of the external layer which is typically susceptible to hot-spots. With the arranged insulation portions, the heat generated from the heat-generating electrical components transfers laterally along the thermal spreader layer toward each of the conductive portions of the interface layer. The conductive portions are thermally-conductive to transfer heat from the thermal spreader layer to the external layer in certain areas away from the heat-generating electrical components. In some embodiments, the conductive portions are arranged along the edges of the package, within the interface layer, in order to improve the thermal distribution throughout the external layer outer surface. This improved thermal distribution of the heat to different parts of the external layer reduces the likelihood of hot-spots forming on the external layer outer surface.

The thermal spreader layer of the package is arranged such that a thermal spreader outer surface is in contact with an interface layer inner surface. The thermal spreader layer may be partitioned into three types of features: thermally-conductive plates, thermally-conductive channels, and thermal pooling sections. Each of the thermally conductive plates is arranged in thermal contact with a respective heat-generating electrical component of the circuitry as well as insulated from the external layer inner surface by an insulation portion of the interface layer. Each channel of the thermal spreader layer is in thermal contact with at least one of the thermally-conductive plates and at least one thermal pooling section to transfer heat along the channel from the conductive plate to the thermal pooling section. In some embodiments, each respective channel is placed around the electrical components of the circuitry to prevent thermal transfer from the respective channel to the electrical components of the circuitry, which may reduce or eliminate the amount of thermal throttling of the electrical components. In some embodiments, the thermal pooling sections of the thermal spreader layer are placed along the edges of the package, with at least one channel transferring heat to each thermal pooling section in order for the heat to be transferred away from the heat-generating electrical elements. The thermal pooling sections are in thermal contact with conductive portions of the interface layer to transfer heat from each thermal pooling section to the external layer inner surface.

The circuitry is arranged facing a thermal spreader inner surface, the circuitry including electrical components, at least one of which is a heat-generating electrical component. The heat-generating electrical component may be any suitable high-performance electrical component (e.g., an integrated circuit device, such as an application-specific integrated circuit (ASIC) device). In some embodiments, the circuitry includes a printed circuit board (PCB), which may include multiple dielectric layers, on which the electrical components may be mounted. In some embodiments, a TIM may be positioned between a respective heat-generating electrical component and a respective thermally-conductive plate of the thermal spreader layer.

In some embodiments, the package includes multiple interface layers and multiple thermal spreader layers. For example, the package may include a second interface layer and a second thermal spreader layer. In such an example, the second interface layer and the second thermal spreader layer are disposed between the first thermal spreader layer (previously referred to as the thermal spreader layer) and circuitry. Similarly to the first interface layer, the second interface layer includes a second interface layer outer surface, which is arranged in contact with the first thermal spreader layer inner surface. The second thermal spreader layer includes a second thermal spreader outer surface and a second thermal spreader inner surface. The second thermal spreader outer surface is arranged in contact with a second interface layer inner surface, and the circuitry is disposed proximate to and facing the second thermal spreader inner surface. In some embodiments, there are more than two interface layers and more than two thermal spreader layers. In such embodiments, no respective interface layer is disposed in contact with another interface layer and no respective thermal spreader layer is disposed in contact with another thermal spreader layer.

For purposes of brevity and clarity, the features of the disclosure described herein are in the context of a package with an external layer, interface layer, thermal spreader layer and circuitry. However, the principles of the present disclosure may be applied to any other suitable context in which an enclosure for the circuitry is used.

In particular, the present disclosure provides packages and methods for manufacturing thereof, where the package has an improved thermal distribution to reduce the likelihood of hot-spots on the external layer outer surface. The packages and methods for manufacturing thereof provided included arranged a thermal spreader layer and interface layer to reduce or eliminate non-uniform thermal distributions on the external layer of the package. This also ensures that the surface temperature of the external layer remains below the safety and regulatory requirement touch temperature limit and reduces or eliminates any chance of thermal throttling of the circuitry in the package.

In some embodiments, the circuitry of the package may include any suitable processing circuitry, which may include any suitable processing chip (e.g., an application-specific integrated circuit (ASIC) chip) or processing core.

In some embodiments the package and methods for manufacturing the package of the present disclosure may include a circuitry which functions as a storage device system (e.g., an SSD storage system), which includes a storage device such as a solid-state drive device.

An SSD is a data storage device that uses integrated circuit assemblies as memory to store data persistently. SSDs have no moving mechanical components, and this feature distinguishes SSDs from traditional electromechanical magnetic disks, such as, hard disk drives (HDDs) or floppy disks, which contain spinning disks and movable read/write heads. Compared to electromechanical disks, SSDs are typically more resistant to physical shock, run silently, have lower access time, and less latency.

Many types of SSDs use NAND-based flash memory which retain data without power and include a type of non-volatile storage technology. Quality of Service (QOS) of an SSD may be related to the predictability of low latency and consistency of high input/output operations per second (IOPS) while servicing read/write input/output (I/O) workloads. This means that the latency or the I/O command completion time needs to be within a specified range without having unexpected outliers. Throughput or I/O rate may also need to be tightly regulated without causing sudden drops in performance level.

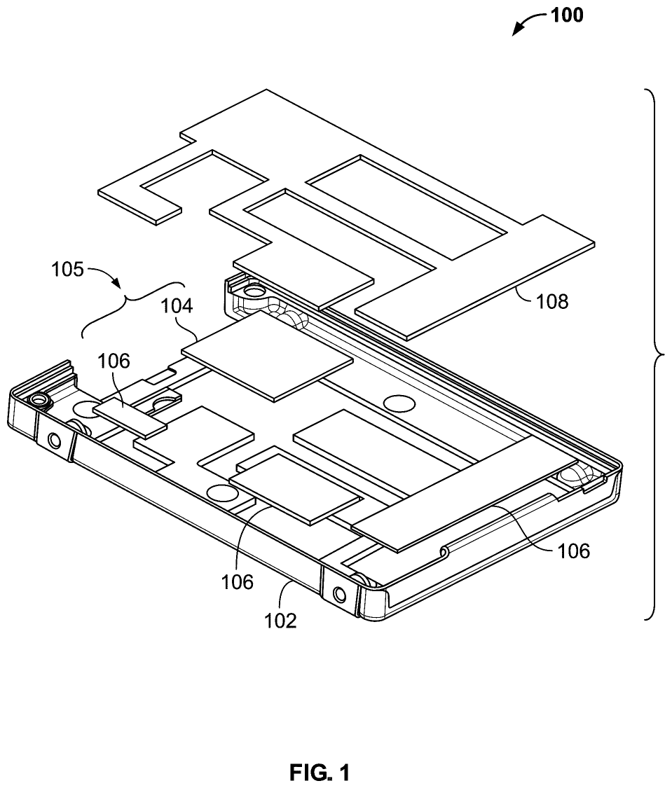

The subject matter of this disclosure may be better understood by reference to FIGS. 1-9.

FIG. 1 shows an illustrative exploded view diagram of a package 100 with a thermal spreader layer 108, in accordance with some embodiments of the present disclosure. The package 100 includes an external layer 102, the thermal spreader layer 108 and an interface layer 105 with at least one insulation portion 104 and at least one conductive portion 106. The external layer 102 defines an external layer outer surface and an external layer inner surface. The interface layer 105 may be defined by an interface layer inner surface and an interface layer outer surface which is in contact with the external layer inner surface of the external layer 102. The thermal spreader layer 108 may define a thermal spreader inner surface and a thermal layer outer surface which is in contact with the interface layer inner surface of the interface layer 105. The package 100 also includes circuitry (not shown), which is arranged proximate to and facing the thermal spreader inner surface of the thermal spreader layer 108.

In some embodiments, the circuitry includes at least one electrical component, any respective one of which may generate heat while in operation. The thermal spreader layer 108 is arranged to be in thermal contact with the heat-generating electrical component in order for heat to transfer along the thermal spreader layer 108, away from the heat-generating electrical component. In some embodiments, a thermal interface material (TIM) is disposed between the heat-generating electrical component of the circuitry and the thermal spreader inner surface of the thermal spreader layer 108.

Each of the thermal spreader layer 108 and the external layer 102 are thermally-conductive. The thermal spreader layer 108 is thermally-conductive to promote heat transfer of heat generated from at least one electrical component in operation away from the at least one heat-generating electrical component in order to reduce the likelihood of hot-spots on the external layer 102. The external layer 102 is thermally-conductive in order to dissipate heat generated from the at least one electrical component in operation. The interface layer 105 is arranged between the external layer 102 and the thermal spreader layer 108 in order to facilitate the heat transfer in such a manner to reduce the likelihood of hot-spots on the external layer 102.

The insulation portions 104 of the interface layer 105 are arranged between the thermal spreader layer 108 and the external layer 102, each insulation portion 104 disposed in the thermal contact with a portion of the thermal spreader layer 108 which is in thermal contact with one of the at least one heat-generating electrical components. The insulation portions 104 may be any thermally-insulative material (e.g. a pocket of air). The insulation portions 104 are arranged in order to reduce the direct thermal transfer from each heat-generating electrical component by insulating the thermal spreader layer 108 from being in thermal contact with a portion of the external layer 102 which is typically susceptible to hot-spots. With the arranged insulation portions 104, the heat generated from the at least one heat-generating electrical components may transfer laterally along the thermal spreader layer 108 toward each of the at least one conductive portions 106 of the interface layer 105. The conductive portions 106 of the interface layer 105 are disposed coplanar and laterally from the insulation portions 104. The conductive portions 106 are thermally conductive and in some embodiments, each of the conductive portions 106 may be thermal interface material (TIM) to provide heat transfer from the thermal spreader layer 108 to the external layer 102. In some embodiments, the interface layer 105 omits the conductive portions 106 and relies on thermal radiation through pockets of air disposed between the thermal spreader layer 108 and the external layer 102. The conductive portions 106 are disposed within the interface layer 105 along the edges of the package 100 in order for the heat generated from the at least one heat-generating electrical components to be transferred away from the areas of the package proximate the heat-generating electrical components. This enables the distribution of the heat to different parts of the external layer 102, reducing the likelihood of hot-spots forming on the external layer 102.

It will be understood that, while package 100 depicts an embodiment in which circuitry is encapsulated by the external layer and other layers in accordance with the present disclosure, any other suitable thermally-conductive housing may be implemented in a similar manner. Additionally, although package 100 depicts an embodiments in which there is one interface layer 105 and one thermal spreader layer 108, package 100 may include more than one interface layer 105 and more than one thermal spreader layer 108 such that a number of interface layers 105 disposed within package 100 is the same as a number of thermal spreader layers 108 within package 100.

For purposes of clarity and brevity, and not by way of limitation, the present disclosure is provided in the context of a package 100 and the manufacturing thereof, which provide the features and functionalities disclosed herein. The package 100 may be at least partially implemented with, for example, a server device or storage device.

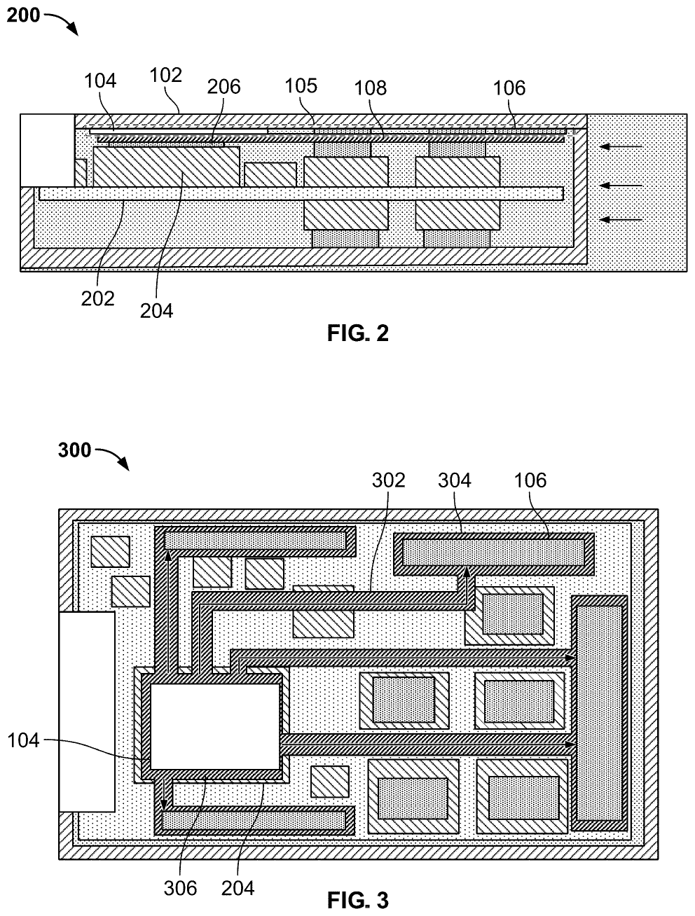

FIG. 2 shows an illustrative cross-sectional diagram of a package 200 with a thermal spreader layer 108, in accordance with some embodiments of the present disclosure. The package 200 includes a printed circuit board (PCB) 202 and circuitry 204. In some embodiments, the PCB 202 may be referred to as a part of circuitry 204. Circuitry 204 includes at least one electrical component, where at least one electrical component is a heat-generating electrical component. Circuitry 204 is arranged such that the at least one heat-generating component is in thermal contact with a thermal spreader layer inner surface of thermal spreader layer 108. In some embodiments, a thermal interface material (TIM) 206 may be disposed between the thermal spreader layer 108 and each of the at least one heat-generating electrical component of circuitry 204. In some embodiments, TIM 206 may be any suitable thermally-conductive material to promote heat transfer from the at least one heat-generating electrical component of circuitry 204 to the thermal spreader layer 108.

A thermal spreader layer outer surface of the thermal spreader layer 108 is contact with an interface layer inner surface of the interface layer 105. As discussed above, the interface layer 105 includes at least one insulation portion 104 is disposed in contact with the thermal spreader layer outer surface above the at least one heat-generating electrical components of circuitry 204. The interface layer 105 also includes at least one conductive portions, which are placed coplanar to and laterally from the at least one insulation portion 104. The conductive portions 106 are disposed along the edges of package 200, away from an area proximate to the at least one heat-generating electrical components. In some embodiments, the conductive portions 106 may be any suitable thermally conductive material (e.g., a thermal interface material (TIM)), to provide thermal transfer from the thermal spreader layer 108 to the external layer 102.

An interface layer outer surface of the interface layer 105 may be in contact with an external layer inner surface of the external layer 102. The external layer 102 is made of thermally-conductive material (e.g., aluminum) to function as a heat sink for heat generated by circuitry 204. The external layer 102 is arranged such that heat dissipation occurs from an external layer outer surface of the external layer 102.

FIG. 3 shows an illustrative plan view diagram of the package 300, similar to package 200 of FIG. 2, in accordance with some embodiments of the present disclosure. The package 300 includes external layer 102 with an external layer outer surface and an external layer inner surface. The external layer 102 of package 300 is thermally conductive in order dissipate heat generated from circuitry 204, specifically any heat-generating electrical components. In some embodiments, the external layer 102 may be a part of housing of an enclosure which encapsulates the layers (e.g., interface layer 105, thermal spreader layer 108 and circuitry 204) disclosed herein.

The interface layer is arranged such that an interface layer outer surface is in contact with the external layer inner surface. The interface layer includes at least one insulation portion 104 and at least one conductive portion 106. Each insulation portion is disposed in contact with a conductive plate 306 of the thermal spreader layer, the conductive plate 306 in thermal contact with one of the heat-generating electrical components of circuitry 204. The arranged insulation portions promote thermal transfer of heat generated from the one heat-generating electrical components laterally along at least one thermally-conductive channel 302 toward a respective thermal pooling section 304 of the thermal spreader layer. The conductive portions 106 of the interface layer are disposed coplanar to and laterally from the insulation portions 104. Each conductive portion 106 is thermally conductive and in some embodiments, each of the conductive portions 106 may be a TIM to provide heat transfer from a thermal pooling section 304 to the external layer 102. The conductive portions 106 are disposed within the interface layer along the edges of the package 300 in order for the heat generated from the heat-generating electrical components to be transferred away from the areas of the package 300 proximate the heat-generating electrical components. This enables the eventual distribution of the heat to different parts of the external layer 102, reducing the likelihood of hot-spots forming on the external layer outer surface.

The thermal spreader layer is arranged such that the thermal spreader layer outer surface is in contact with an interface layer inner surface. The thermal spreader layer includes at least one thermally-conductive plate 306, at least one thermally-conductive channel 302 and at least one thermal pooling section 304. Each of the thermally conductive plates 306 is arranged in thermal contact with a heat-generating electrical component of the circuitry 204 and insulated from the external layer inner surface by an insulation portion 104 of the interface layer. Each channel 302 is arranged in thermal contact with at least one of the thermally-conductive plates 306 and at least one thermal pooling section 304 to transfer heat along the channel 302 from the conductive plate 306 to the thermal pooling section 304. The layout for each respective channel 302 is arranged to prevent thermal transfer from a respective channel 302 to any of the at least one electrical component of circuitry 204 to avoid thermal throttling of the electrical components. Each thermal pooling section 304 of the thermal spreader layer is arranged along the edges of the package 300, with at least one channel 302 transferring heat to a thermal pooling section 304. Each of the thermal pooling sections 304 is in thermal contact with the conductive portion 106 of the interface layer, wherein the conductive portion 106 enables thermal transfer from the thermal pooling section 304 to the external layer 102.

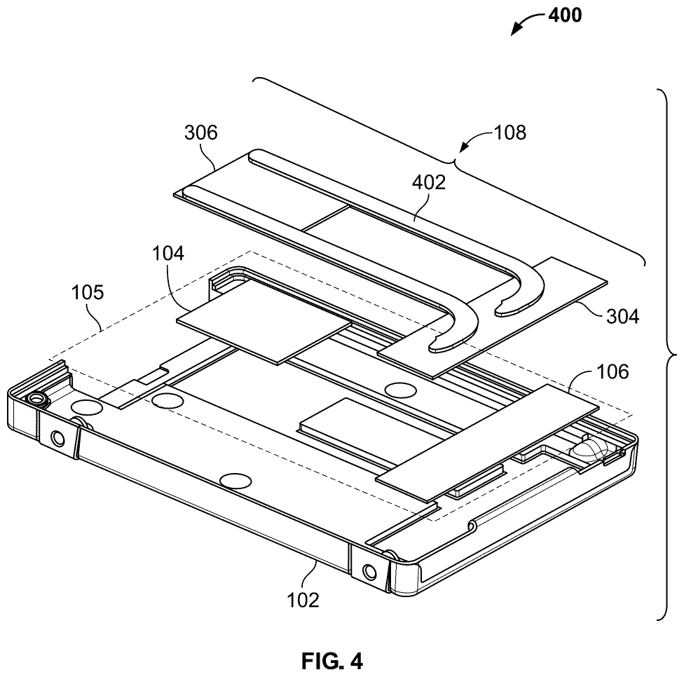

FIG. 4 shows an illustrative exploded view diagram of another implementation of a package 400 with a thermal spreader layer 105, similar to package 100 of FIG. 1. This implementation of the package 400, includes a thermal spreader layer 105 arranged with at least one conductive plate 306, at least one thermal pooling section and heat pipes 402, which provide thermal transfer from a respective conductive plate 306 to a respective thermal pooling section 304. The heat pipes 402 may be arranged in any suitable package (e.g., package 400), to replace the at least one channel as seen in FIGS. 1-3. Each of the heat pipes 402 is disposed in the thermal spreader layer to reduce the thermal transfer from the respective heat pipe 402 to any of the electrical component of the circuitry to avoid thermal throttling of the electrical components.

Similarly to the package 100 in FIG. 1, the package 400 includes an external layer 102, the thermal spreader layer 108 and an interface layer 105 with at least one insulation portion 104 and at least one conductive portion 106. The package 400 also includes circuitry (not shown), which is arranged proximate to and facing a thermal spreader inner surface of the thermal spreader layer 108.

The insulation portions 104 of the interface layer 105 are arranged between the thermal spreader layer 108 and the external layer 102, each insulation portion 104 disposed in the contact with a respective conductive plate 306. With the arranged insulation portions 104, the heat generated from the at least one heat-generating electrical components may transfer laterally along the heat pipes 402 toward each of the thermal pooling sections 304, which is in thermal contact with a respective conductive portion 106 of the interface layer 105. The conductive portions 106 of the interface layer 105 are disposed coplanar and laterally from the insulation portions 104. The conductive portions 106 are thermally conductive and in some embodiments, each of the conductive portions 106 may be thermal interface material (TIM) to provide heat transfer from the thermal pooling section 304 to the external layer 102.

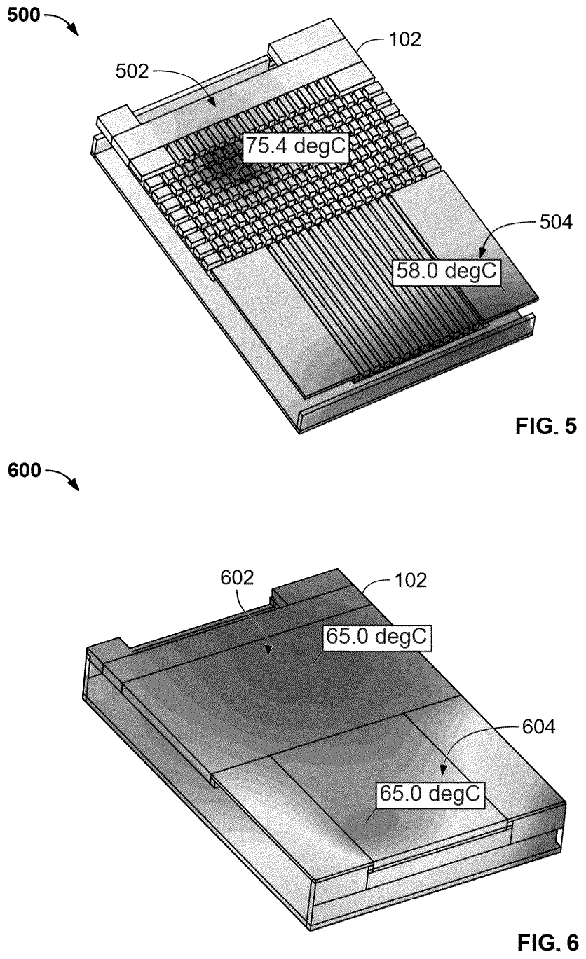

FIG. 5 shows an illustrative diagram for temperature distributions along the external layer 102 of a package 500 without a thermal spreader layer, in accordance with some embodiments of the present disclosure. A first area 502 of the package 500 includes a hot-spot, such that the surface temperature of the external layer 102 is 75.4° C., while a second area 504 has a surface temperature of 58.0° C. This difference in respective surface temperatures of the first area 502 and the second area 504 indicates that the package 500 is providing poor thermal distribution of heat generated within the package 500. The hot-spot at first area 502 may indicate that the area at which a source is generating heat within the package.

FIG. 6 shows an illustrative diagram for temperature distributions along the external layer 102 of a package 600 with a thermal spreader layer, in accordance with some embodiments of the present disclosure. The respective external temperature for each of a first area 602 and a second area 604 is 65° C., which shows an improved thermal distribution along the external layer 102 when compared to the thermal distribution of package 500.

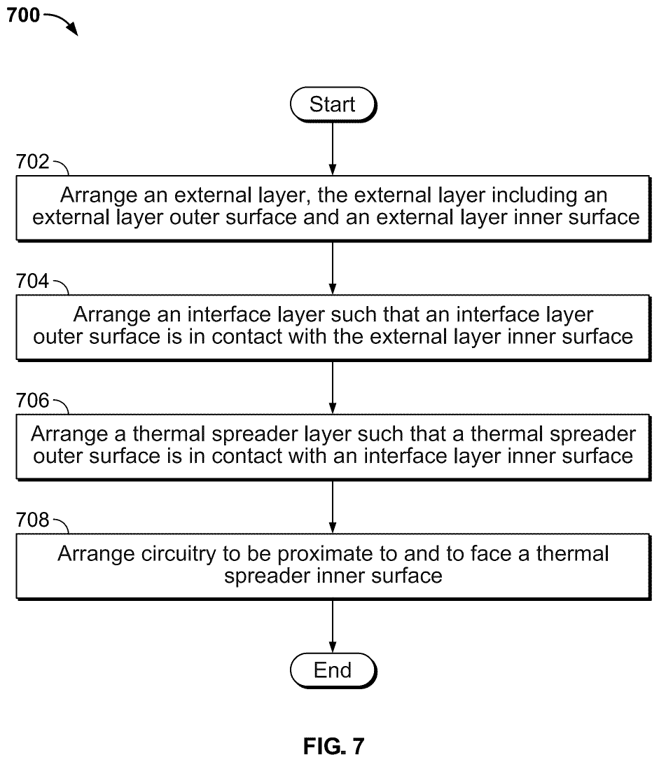

FIG. 7 shows a flowchart of illustrative steps for a process 700 for manufacturing a package with a thermal spreader layer, in accordance with some embodiments of the present disclosure. In some embodiments, the referenced external layer, interface layer, thermal spreader layer, circuitry, insulation portion, conductive portion, thermally-conductive plate, thermally conductive channel, and thermal pooling section may be implemented as external layer 102, interface layer 105, thermal spreader layer 108, circuitry 204, insulation portion 104, conductive portion 106, thermally-conductive plate 306, thermally conductive channel 302 and thermal pooling section 304 respectively. In some embodiments, the process 700 can be modified by, for example, having steps rearranged, changed, added, and/or removed.

At step 702, arrange an external layer, the external layer including an external layer outer surface and an external layer inner surface. The external layer of the package is thermally conductive in order dissipate heat generated from the circuitry, specifically any heat-generating electrical components. In some embodiments, the external layer may be a part of housing of an enclosure which encapsulates the layers disclosed herein.

At step 704, arrange an interface layer such that an interface layer outer surface is in contact with the external layer inner surface. The interface layer includes at least one insulation portion and at least one conductive portion. Each insulation portion is disposed in contact with a portion of the thermal spreader layer which is in thermal contact with one of at least one heat-generating electrical components of the circuitry. The insulation portions may be any thermally-insulative material. The insulation portions are arranged in order to reduce the direct thermal transfer from each heat-generating electrical component by insulating the thermal spreader layer from being in thermal contact with a portion of the external layer which is typically susceptible to hot-spots. With the arranged insulation portions, the heat generated from the at least one heat-generating electrical components may transfer laterally along the thermal spreader layer toward each of the at least one conductive portions of the interface layer. The conductive portions are disposed coplanar to and laterally from the insulation portions. Each conductive portion is thermally conductive and, in some embodiments, each of the conductive portions may be a TIM to provide heat transfer from the thermal spreader layer to the external layer. The conductive portions are disposed within the interface layer along the edges of the package in order for the heat generated from the at least one heat-generating electrical components to be transferred away from the areas of the package proximate the heat-generating electrical components. This enables the distribution of the heat to different parts of the external layer, reducing the likelihood of hot-spots forming on the external layer.

At step 706, arrange the thermal spreader layer such that a thermal spreader outer surface is in contact with an interface layer inner surface. The arranged thermal spreader layer includes at least one thermally-conductive plate, at least one thermally-conductive channel and at least one thermal pooling section. Each of the thermally conductive plates is arranged in thermal contact with a heat-generating electrical component of the circuitry and insulated from the external layer inner surface by an insulation portion of the interface layer. Each channel of the thermal spreader layer is in thermal contact with at least one of the thermally-conductive plates and at least one thermal pooling section to transfer heat along the channel from the conductive plate to the thermal pooling section. Each respective channel is disposed in the thermal spreader layer to prevent thermal transfer from the respective channel to any of the at least one electrical component of the circuitry to avoid thermal throttling of the electrical components. Each thermal pooling section of the thermal spreader layer is arranged along the edges of the package, with at least one channel transferring heat to each thermal pooling section. Each thermal pooling section is in thermal contact with the conductive portion of the interface layer, wherein the conductive portion enables thermal transfer from the thermal pooling section to the external layer.

At step 708, arrange circuitry to be proximate to and to face a thermal spreader inner surface. The arranged circuitry includes at least one electrical component, where at least one of the electrical components is a heat-generating electrical component. The heat-generating electrical component may be any suitable high-performance electrical component (e.g., an integrated circuit device, such as an application-specific integrated circuit (ASIC) device). The circuitry includes a printed circuit board (PCB), which may include multiple dielectric layers, on which the at least one electrical components may be mounted. In some embodiments, a TIM may be disposed between a respective heat-generating electrical component and a respective thermally-conductive plate of the thermal spreader layer. In some embodiments, the layout design for the thermally-conductive channels of the thermal spreader layer is dependent on the arranged electrical components of the circuitry. The at least one channel is arranged to reduce the amount of thermal transfer from a respective channel to any of the at least one electrical components of the circuitry.

In some embodiments, process 700 may include additional steps to arrange multiple interface layers and arrange multiple thermal spreader layers. For example, a second interface layer and a second thermal spreader layer are disposed between the first thermal spreader layer (previously referred to as the thermal spreader layer) and circuitry. A second interface layer outer surface of the second interface layer is arranged in contact with the first thermal spreader layer inner surface. Additionally, a second thermal spreader outer surface is arranged in contact with a second interface layer inner surface. The circuitry is then disposed proximate to and facing a second thermal spreader inner surface. In some embodiments, there are more than two interface layers and more than two thermal spreader layers. In such embodiments, no respective interface layer is disposed in contact with another interface layer and no respective thermal spreader layer is disposed in contact with another thermal spreader layer.

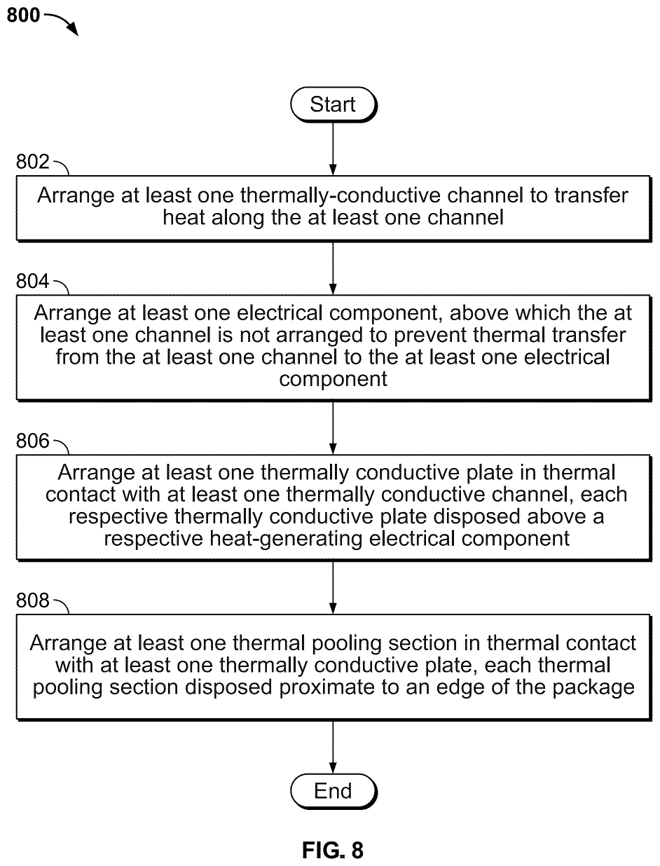

FIG. 8 shows a flowchart of illustrative steps for a process 800 for arranging the thermal spreader layer of a package, in accordance with some embodiments of the present disclosure. In some embodiments, the referenced external layer, interface layer, thermal spreader layer, circuitry, insulation portion, conductive portion, thermally-conductive plate, thermally conductive channel, and thermal pooling section may be implemented as external layer 102, interface layer 105, thermal spreader layer 108, circuitry 204, insulation portion 104, conductive portion 106, thermally-conductive plate 306, thermally conductive channel 302 and thermal pooling section 304 respectively. In some embodiments, the process 800 can be modified by, for example, having steps rearranged, changed, added, and/or removed.

At step 802, arrange at least one thermally-conductive channel to transfer heat along the at least one channel. The channels are arranged to promote distributed thermal transfer throughout the package to reduce or eliminate the likelihood of hot-spots occurring on the external layer outer surface.

At step 804, arrange at least one electrical component, above which the at least one channel is not arranged to prevent thermal transfer from the at least one channel to the at least one electrical component. The electrical components are part of the circuitry of the package. In some embodiments, the circuitry includes a PCB, which may include multiple dielectric layers, on which the at least one electrical components may be mounted. In some embodiments, the channels of the thermal spreader layer is arranged around electrical components of the circuitry to reduce the amount of thermal transfer from a respective channel to any of the at least one electrical components of the circuitry.

At step 806, arrange at least one thermally conductive plate in thermal contact with at least one thermally conductive channel, each respective thermally conductive plate disposed above a respective heat-generating electrical component. In some embodiments, a TIM is disposed between a respective heat-generating electrical component and a respective conductive plate to ensure thermal contact and thermal transfer from the respective heat-generating electrical component and the respective conductive plate. The heat transferred from the heat-generating electrical components continues along the at least one thermally-conductive channel in thermal contact with the conductive plate.

At step 808, arrange at least one thermal pooling section in thermal contact with at least one thermally conductive plate, each thermal pooling section disposed proximate to an edge of the package. Each of the thermal pooling sections are in thermal contact with at least one conductive plate by way of at least one thermally-conductive channel. The heat transferred along a respective channel from a conductive plate continues to a respective thermal pooling section, which is in thermal contact with a conductive portion of the interface layer. In addition, each thermal pooling section of the thermal spreader layer is arranged along the edges of the package to provide an improved thermal distribution to the external layer.

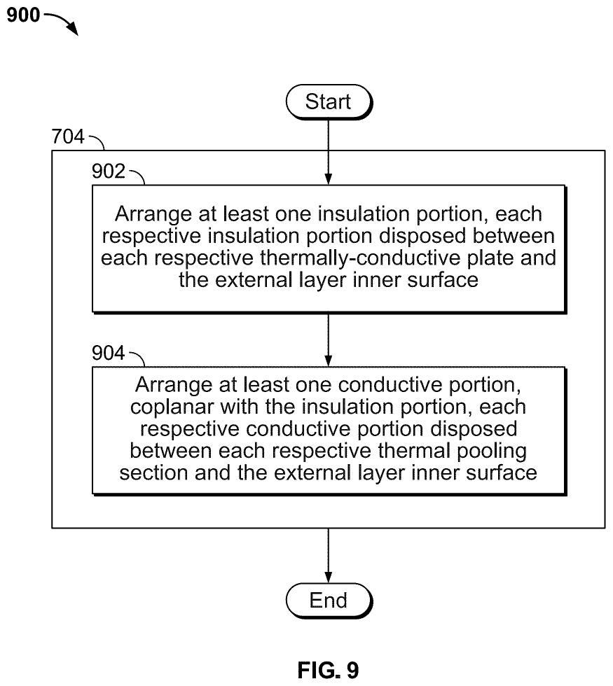

FIG. 9 shows a flowchart of illustrative steps of a subprocess 900 for arranging the interface layer, as shown at step 704 in FIG. 7, in accordance with some embodiments of the present disclosure. In some embodiments, the referenced external layer, interface layer, thermal spreader layer, circuitry, insulation portion, conductive portion, thermally-conductive plate, thermally conductive channel, and thermal pooling section may be implemented as external layer 102, interface layer 105, thermal spreader layer 108, circuitry 204, insulation portion 104, conductive portion 106, thermally-conductive plate 306, thermally conductive channel 302 and thermal pooling section 304 respectively. In some embodiments, the subprocess 900 can be modified by, for example, having steps rearranged, changed, added, and/or removed.

At step 902, arrange at least one insulation portion, each respective insulation portion disposed between each respective thermally-conductive plate and the external layer inner surface. Each insulation portion is of any suitable thermally-insulative material, including but not limited to, an insulative form, a pocket of air, or channel of flowable air. The insulation portions are arranged to deter thermal transfer from the conductive plates, which are positioned in thermal contact with a respective heat-generating electrical component, directly to the external layer. This arrangement of insulation portions promote thermal transfer from each respective conductive plate along any channels that are in thermal contact with each respective conductive plate. The lateral thermal transfer through the channels of the thermal spreader layer continues to at least one thermal pooling section.

At step 904, arrange at least one conductive portion, coplanar with the insulation portion, each respective conductive portion disposed between each respective thermal pooling section and the external layer inner surface. In some embodiments, one or more of the conductive portions of the interface layer may be omitted. In such embodiments, pockets of air may be disposed between the thermal spreader layer and the external layer heat is transferred from the thermal spreader layer to the external layer by thermal radiation through the pockets of air. Each conductive portion of the interface layer is of any suitable thermally-conductive material, including but not limited to, a TIM. The conductive portions are arranged to allow thermal transfer from the thermal pooling sections directly to the external layer. Each of the thermal pooling sections are portions of the thermal spreader layer which receive heat from heat-generating electrical components by way of the conductive plates and channels. In some embodiments, each of the thermal pooling sections is positioned along the edges of the package, away from the area proximate to the at least one heat-generating electrical components. This arrangement ensures improved heat distribution throughout the package in order to reduce the likelihood of hot-spots occurring on the external layer outer surface.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments. Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least certain operations that may have been illustrated in the figures show certain events occurring in a certain order. In alternative embodiments, certain operations may be performed in a different order, modified, or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to be limited to the precise forms disclosed. Many modifications and variations are possible in light of the above teaching.

What is claimed is:

1. A package comprising a plurality of layers, the layers comprising:
an external layer comprising an external layer outer surface and an external layer inner surface;
an interface layer comprising an interface layer outer surface and an interface layer inner surface, the interface layer outer surface in contact with the external layer inner surface;
a thermal spreader layer comprising a thermal spreader outer surface and a thermal spreader inner surface, the thermal spreader outer surface in contact with the interface layer inner surface; and
circuitry, arranged proximate to and facing the thermal spreader inner surface.

2. The package of claim 1, wherein each of the external layer and the thermal spreader layer is comprised of thermally-conductive material.

3. The package of claim 1, wherein the thermal spreader layer further comprises at least one thermally-conductive channel to transfer heat along the at least one channel.

4. The package of claim 3, wherein the circuitry comprises at least one electrical component, above which the at least one channel is not arranged to prevent thermal transfer from the at least one channel to the at least one electrical component.

5. The package of claim 1, wherein the thermal spreader layer further comprises at least one thermally conductive plate in thermal contact with at least one thermally conductive channel, each respective thermally conductive plate disposed above a respective heat-generating electrical component.

6. The package of claim 5, wherein the interface layer further comprises:
at least one insulation portion, each respective insulation portion disposed between each respective thermally-conductive plate and the external layer inner surface; and
at least one conductive portion, coplanar with the insulation portion, each respective conductive portion disposed between each respective thermal pooling section and the external layer inner surface.

7. The package of claim 1, wherein the thermal spreader layer further comprises:
at least one thermally-conductive plate; and
at least one thermal pooling section; wherein:
each thermal pooling section is in thermal contact with at least one thermally conductive plate and each thermal pooling section is disposed proximate to an edge of the package.

8. The package of claim 7, further comprising at least one thermally-conductive channel, wherein each thermally-conductive channel is in thermal contact with at least one thermally conductive plate and at least one thermal pooling section.

9. The package of claim 1, further comprising a thermal interface material (TIM) disposed between the circuitry and the thermal spreader inner surface.

10. The package of claim 1, wherein the circuitry comprises a printed circuit board (PCB).

11. The package of claim 1, further comprising an enclosure encapsulating the plurality of layers, the enclosure comprising the external layer.

12. The package of claim 1, wherein a temperature of the external layer remains below a safety and regulatory touch temperature limit.

13. The package of claim 1, further comprising:
a second interface layer comprising a second interface layer outer surface and a second interface layer inner surface, the second interface layer outer surface in contact with the thermal spreader layer inner surface; and
a second thermal spreader layer comprising a second thermal spreader outer surface and a second thermal spreader inner surface, the second thermal spreader outer surface is arranged in contact with the second interface layer inner surface, and the circuitry proximate to and facing the second thermal spreader inner surface.

14. A method for manufacturing a package, the method comprising:
arranging an external layer, the external layer comprising an external layer outer surface and an external layer inner surface;
arranging an interface layer such that an interface layer outer surface is in contact with the external layer inner surface;
arranging a thermal spreader layer such that a thermal spreader outer surface is in contact with an interface layer inner surface; and
arranging circuitry to be proximate to and to face a thermal spreader inner surface.

15. The method, according to claim 14, for manufacturing a package, wherein each of the external layer and the thermal spreader layer is comprised of thermally-conductive material.

16. The method, according to claim 14, for manufacturing a package, wherein arranging the thermal spreader layer comprises arranging at least one thermally-conductive channel to transfer heat along the at least one channel.

17. The method, according to claim 16, for manufacturing a package, wherein arranging circuitry comprises arranging at least one electrical component, above which the at least one channel is not arranged to prevent thermal transfer from the at least one channel to the at least one electrical component.

18. The method, according to claim 14, for manufacturing a package, wherein arranging the thermal spreader layer comprises arranging at least one thermally conductive plate in thermal contact with at least one thermally conductive channel, each respective thermally conductive plate disposed above a respective heat-generating electrical component.

19. The method, according to claim 18 for manufacturing a package, wherein arranging an interface layer comprises:
arranging at least one insulation portion, each respective insulation portion disposed between each respective thermally-conductive plate and the external layer inner surface; and
arranging at least one conductive portion, coplanar with the insulation portion, each respective conductive portion disposed between each respective thermal pooling section and the external layer inner surface.

20. The method, according to claim 14, for manufacturing a package, wherein arranging the thermal spreader layer comprises:
arranging at least one thermally-conductive plate; and
arranging at least one thermal pooling section in thermal contact with at least one thermally conductive plate, each thermal pooling section disposed proximate to an edge of the package.

21. The method, according to claim 20 for manufacturing a package, the method further comprising arranging at least one thermally-conductive channel, wherein each channel is arranged in thermal contact with at least one thermally-conductive plate and at least one thermal pooling section.

22. The method, according to claim 14, for manufacturing a package, further comprising applying a thermal interface material (TIM) between the circuitry and the thermal spreader inner surface.

23. The method, according to claim 14, for manufacturing a package, further comprising:
arranging a printed circuit board (PCB) layer, and
mounting the circuitry onto the PCB layer.

24. The method, according to claim 14, for manufacturing a package, further comprising enclosing the package in an enclosure, wherein the enclosure comprises the external layer.

25. The method, according to claim 14, for manufacturing a package, further comprising:
arranging a second interface layer such that a second interface layer outer surface is in contact with the thermal spreader layer inner surface; and
arranging a second thermal spreader layer such that a second thermal spreader outer surface is in contact with a second interface layer inner surface and the circuitry is proximate to and facing a second thermal spreader inner surface.

26. An enclosure comprising:
housing, wherein the housing encapsulates a plurality of layers, the plurality of layers comprising:
an external layer comprising an external layer outer surface and an external layer inner surface;
an interface layer comprising an interface layer outer surface and an interface layer inner surface, the interface layer outer surface in contact with the external layer inner surface;
a thermal spreader layer comprising a thermal spreader outer surface and a thermal spreader inner surface, the thermal spreader outer surface in contact with the interface layer inner surface; and
circuitry, arranged proximate to and facing the thermal spreader inner surface.
